(19) United States
(12) Patent Application Publication
(10) Pub. No.: US 2014/0043887 A1
(43) Pub. Date: Feb. 13, 2014

(54) WRITE DRIVER CIRCUIT, SEMICONDUCTOR APPARATUS USING THE SAME, AND MEMORY SYSTEM

(71) Applicant: SK HYNIX INC., Icheon-si Gyeonggi-do (KR)

(72) Inventors: Sang Kug LYM, Icheon-si (KR); Ho Seok EM, Icheon-si (KR)

(73) Assignee: SK HYNIX INC., Icheon-si (KR)

(21) Appl. No.: 13/720,739

(22) Filed: Dec. 19, 2012

(30) Foreign Application Priority Data
Aug. 10, 2012 (KR) 10-2012-0087599

(51) Int. Cl. G11C 13/00; G11C 11/16

(52) U.S. Cl. CPC G11C 13/0069; G11C 13/0002; G11C 13/0004; G11C 11/16
USPC 365/148; 365/189.16; 365/163; 365/158

(57) ABSTRACT

A write driver circuit includes a write control unit and a write driver. The write control unit is configured to generate a write control current according to data to be stored. The write driver is configured to generate a write current for writing the data into a memory cell, in response to the write control current and an address signal, wherein the write driver changes the magnitude of the write current according to the write control current and the address signal.

### CROSS-REFERENCES TO RELATED APPLICATION

The present application claims priority under 35 U.S.C. §119(a) to Korean application number 10-2012-0087599, filed on Aug. 10, 2012, in the Korean Intellectual Property Office, which is incorporated herein by reference in its entirety.

### BACKGROUND

1. Technical Field

The present invention relates generally to a semiconductor apparatus, and more particularly, to a write driver circuit of a semiconductor apparatus and a memory system.

2. Related Art

In general, DRAM includes a memory cell array composed of capacitors, and stores data by charging or discharging the capacitors. DRAM is widely used in part to its high speed operation. However, because storing data is achieved by charging or discharging capacitors, DRAM has volatile memory characteristics. Next-generation memory apparatuses having nonvolatile memory characteristics while maintaining fast operation speed have been continuously developed. A representative example of the next-generation memory apparatus may include a resistive memory apparatus including a memory cell array formed of a resistive material having a variable resistance value depending on a temperature, current, or voltage. Since the resistive memory apparatus has nonvolatile memory characteristics and operates at a high speed, the resistive memory apparatus has been considered as an alternative memory device to address the shortcomings of DRAM.

FIG. 1 schematically illustrates the configuration of a conventional resistive memory apparatus 10. The resistive memory apparatus 10 includes a memory bank BANK, a row address decoder 14, and a column address decoder 13. The memory bank BANK includes a plurality of word lines WL0 to WLk and a plurality of bit lines BL0 to BLI. The respective bit lines BL0 to BLI are coupled to receive a write current from the write driver 12, and the write driver 12 is configured to receive a write control current WCC for storing data from a write control unit 11.

Referring to FIG. 1, the memory bank BANK includes a large number of bit lines BL0 to BLI and word lines WL0 to WLk. As the capacity of the memory bank increases and the memory process becomes more integrated, interference between bit lines or between a bit line and a word line significantly increases. Therefore, even when the same data is written into two different memory cells, different data may appear to be written into memory cell B positioned close to the write driver 12 and memory cell A positioned farther from the write driver 12. In particular, when a write current is transmitted to the memory cell A positioned farther from the write driver 12, the write current may be significantly varied.

When the write current is transmitted in a varied manner, accurate data may not be written into the memory cell. The variation of the write current may cause compounded problems in a memory device using a multi-level cell scheme.

### SUMMARY

A write driver capable of transmitting write currents having substantially similar magnitudes regardless of the positions of memory cells and a semiconductor apparatus using the same are described herein.

In an embodiment of the present invention, a write driver circuit includes: a write control unit configured to generate a write control current according to data to be stored, and a write driver configured to generate a write current for writing the data into a memory cell, in response to the write control current and an address signal, wherein the write driver changes the magnitude of the write current according to the write control current and the address signal.

In another embodiment of the present invention, a write driver circuit includes: a write control unit configured to generate a write control current according to data to be stored, a main write driver configured to generate a write current for writing the data into a memory cell, in response to the write control current, and a sub write driver configured to generate the write current in response to the write control current and an address signal.

In another embodiment of the present invention, a semiconductor apparatus includes: a write control unit configured to generate a write control current according to data to be stored, a write driver configured to generate a write current having a magnitude which changes in proportion to a distance to a memory cell to store the data in response to the write control current, a row switch connected to a word line to select the memory cell to store the data in response to a row address signal, and a column switch configured to select a bit line connected to the memory cell to store the data in response to a column address signal.

In another embodiment of the present invention, a memory system includes: a memory host, a write control unit configured to receive a command signal and data from the memory host and generate a write control current, a write driver configured to generate a write current having a magnitude which is changed in proportion to a distance to a memory cell to store the data in response to the write control current, a row switch connected to a word line to select the memory cell to store the data in response to a row address signal, and a column switch configured to select a bit line connected to the memory cell to store the data in response to a column address signal.

### BRIEF DESCRIPTION OF THE DRAWINGS

Features, aspects, and embodiments are described in conjunction with the attached drawings, in which:

FIG. 1 schematically illustrates the configuration of a conventional resistive memory apparatus;

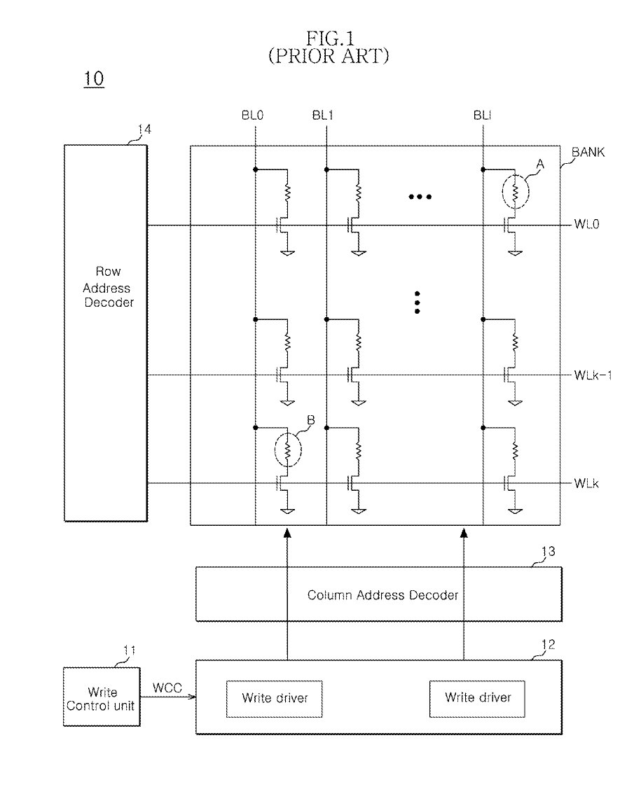

FIG. 2 schematically illustrates the configuration of a write driver circuit according to an embodiment of the present invention;

FIG. 3 illustrates the configuration of a semiconductor apparatus according to an embodiment of the present invention, which includes the write driver of FIG. 2;

FIG. 4 illustrates the configuration of a write control unit of FIG. 2; and

FIG. 5 schematically illustrates the configuration of a memory system according to another embodiment of the present invention.

### DETAILED DESCRIPTION

Hereinafter, a write driver circuit, a semiconductor apparatus using the same, and a memory system according to the present invention will be described below with reference to the accompanying drawings through various embodiments.

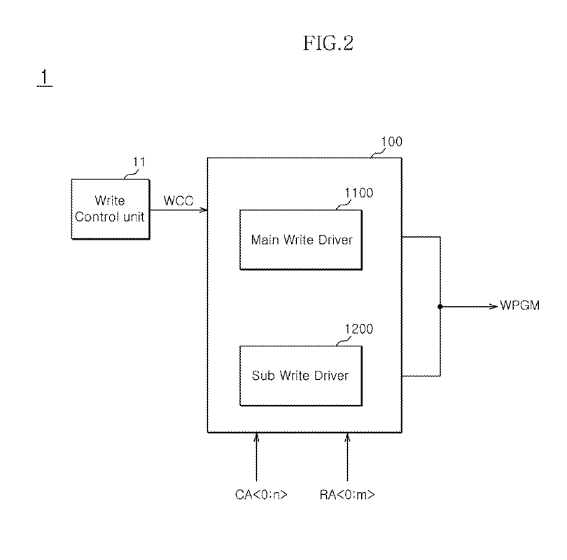

FIG. 2 is a block diagram illustrating the configuration of a write driver circuit 1 according to an embodiment of the present invention. The write driver circuit 1 includes a write control unit 11 and a write driver 100. The write control unit 11 is configured to generate a write control current WCC depending on data to be stored, and may also change the write control current WCC depending on data already stored in a memory cell. That is, the write control unit 11 generates the write control current WCC suitable for programming the memory cell into a set or reset state. The write control unit 11 may receive a write command and data to generate the write control current WCC.

The write driver 100 is configured to generate a write current WPGM according to the write control current WCC and an address signal. The write driver 100 changes the write current WPGM in response to the write current WCC. That is, the write driver 100 may change the magnitude of the write current WPGM in response to the write control current WCC, which itself depends on data stored in a memory cell.

Furthermore, the write driver 100 changes the write current WPGM in response to the address signal. The address signal includes a column address signal CA<0:n> and a row address signal RA<0:m>. The write driver 100 receives the column address signal CA<0:n> and the row address signal RA<0:m> and uses them to determine the position of a memory cell to store data. The write driver 100 may determine a distance between the write driver 100 and the position of the memory cell to change the magnitude of the write current WPGM. For example, when the memory cell to store data is positioned farther from the write driver 100, the magnitude of the write current WPGM may be increased compared to when the memory cell is positioned closer to the write driver 100.

As the semiconductor process becomes more integrated, the number of memory cells existing in a memory bank increases. Therefore, when a memory cell is accessed, interference between signal lines or between memory cells increases, and when a signal generated from a control circuit such as a write driver is transmitted to a memory cell, the interference increases as the distance between the writer driver and memory cell increases. In particular, a resistive memory apparatus including memory cells formed of a resistive material stores data by changing a resistance value depending on the magnitude of a current. However, when a write current is transmitted in a varied manner to a memory cell due to the interference, it is impossible to secure the reliability of a write operation. For example, intended data may be written into a memory cell positioned close to the write driver, but may not correctly be written into a memory cell positioned farther from the write driver.

The write driver circuit 1 according to an embodiment of the present invention may sense how far the memory cell is positioned from the write driver circuit 1, and may change the magnitude of the write current WPGM in proportion to the distance. Under the assumption that same data should be stored at two separate memory cells, the write driver circuit 1 generates a write current WPGM that has a greater magnitude for a memory cell positioned farther from the write driver circuit 1. Therefore, the write driver circuit 1 may stably write desired data into memory cells, regardless of various distances from the write driver 100 to the memory cells.

In an embodiment of the present invention, the memory cell may be formed of a resistive material, a phase change material, or a magnetic material, but is not limited thereto. When the memory cell is formed of a resistive material, the resistance value of the resistive material may be changed according to the write current WPGM so as to store the data. When the memory cell is formed of a phase change material, the crystalline structure of the phase change material may be changed according to the write current WPGM so as to store the data. When the memory cell is formed of a magnetic material, the magnetization direction of the magnetic material may be changed according to the write current WPGM so as to store the data.

In FIG. 2, the write driver 100 includes a main write driver 1100 and a sub write driver 1200. The main write driver 1100 is configured to generate the write current WPGM in response to the write control current WCC. The sub write driver 1200 is configured to generate the write current WPGM in response to the write control current WCC, the column address signal CA<0:n>, and the row address signal RA<0:m>. The main write driver 1100 generates the write current WPGM corresponding to only the change of the write control current WCC. That is, the main write driver 1100 may always generate the write current WPGM regardless of the positions of memory cells. The sub write driver 1200 generates the write current WPGM corresponding to the change of the write control current WCC, and determines whether or not to generate the write current WPGM in response to the address signals CA<0:n> and RA<0:m>. That is, the sub write driver 1200 selectively generates the write current WPGM according to the position of a memory cell to store data.

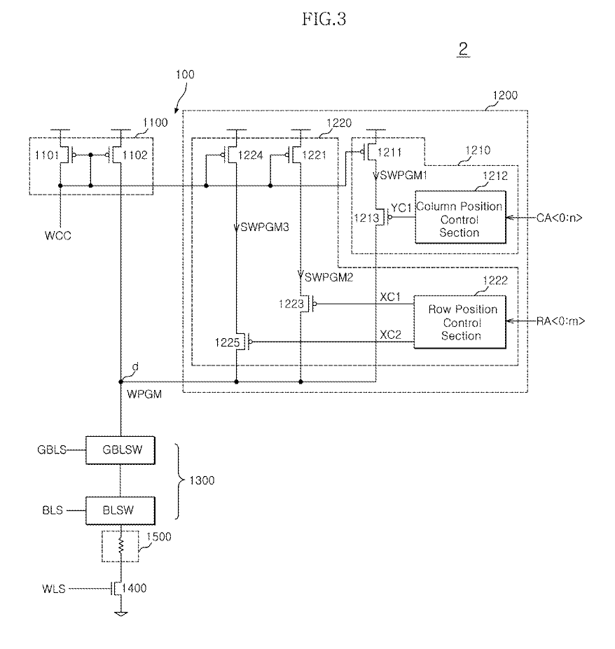

FIG. 3 is a diagram illustrating the configuration of the semiconductor apparatus 2 according to an embodiment of the present invention, which includes the write driver of FIG. 2. Referring to FIG. 3, the semiconductor apparatus 2 includes a write driver 100, a column switch 1300, and a row switch 1400. The column switch 1300 is configured to select a row where a memory cell is positioned, and includes a bit line switch BLSW and a global bit line switch GBLSW. The bit line switch BLSW is a switch for selecting a bit line connected to the memory cell 1500. The global bit line switch GBLSW is a switch for selecting a global bit line connected to the bit line. Since the memory apparatus includes a large number of bit lines, a predetermined number of bit lines are grouped and connected to a global bit line. Therefore, when the row of a memory cell to store or output data is selected, a two-stage selection method of sequentially selecting a global bit line and a bit line is used. When the global bit line is used, the number of column address signals for selecting a bit line may be reduced, and decoding may be efficiently performed.

As described above, the memory cell may be formed of a resistive material, a phase change material, or a magnetic material. Therefore, an embodiment of the present invention may be applied to a resistive memory, a phase change material, a magnetic memory and the like. Furthermore, an embodiment of the present invention may be applied to all types of next-generation memory of which memory cells do not include capacitors.

The bit line switch BLSW may be turned on by a bit line select signal BLS generated by decoding the column address signal CA<0:n>. The global bit line switch GBLSW may be turned on by the global bit line select signal GBLS generated by decoding the column address signal CA<0:n>.

The row switch 1400 is a switch connected to a word line to select the memory cell 1500. The row switch 1400 may form a current path passing through the memory cell 1500, when the word line is enabled to select a column where the memory cell 1500 is positioned.

In FIG. 3, the main write driver 1100 includes first and second PMOS transistors 1101 and 1102. The first PMOS transistor 1101 has a gate and drain configured to receive the write control current WCC and a source connected to a power supply voltage. The second PMOS transistor 1102 has a gate configured to receive the write control current WCC, a source connected to the power supply voltage, and a drain connected to a node d where the write current WPGM is applied. The first PMOS transistor 1101 receives the write control current WCC to perform the function of a current mirror. The second PMOS transistor 1102 performs the function of a driver to generate the write current WPGM, in response to the write control current WCC. Therefore, the main write driver 1100 is configured to generate the write current WPGM corresponding to the magnitude of the write control current WCC.

The sub write driver 1200 includes a column sub driver 1210 and a row sub driver 1220. The column sub driver 1210 is configured to generate the write current WPGM in response to the write control current WCC and the column address signal CA<0:n>. The column sub driver 1210 may change the magnitude of the write current WPGM in response to the column address signal CA<0:n>. The row sub driver 1220 generates the write current WPGM in response to the write control current WCC and the row address signal RA<0:m>. The row sub driver 1220 may change the magnitude of the write current WPGM in response to the row address signal RA<0:m>.

In FIG. 3, the column sub driver 1210 includes a first driver 1211, a column position control section 1212, and a first switch 1213. The first driver 1211 is configured to generate a first sub write current SWPGM1 in response to the write control current WCC. The column position control section 1212 is configured to generate a first control signal YC1 in response to the column address signal CA<0:n>. The column position control section 1212 determines how far a memory cell selected by the column address signal CA<0:n> is positioned away from the write driver 100. When the memory cell is positioned close to the write driver 100, the column position control section 1212 disables the first control signal YC1, and when the memory cell is positioned farther from the write driver 100, the column position control section 1212 enables the first control signal YC1. In an embodiment of the present invention, it has been described that the column position control section 1212 responds to the column address signal CA<0:n>. However, a decoding signal obtained by decoding the column address signal CA<0:n> may be used, like a global bit line select signal.

The first switch 1213 is configured to provide the first sub write current SWPGM1 to node d where the write current is applied, in response to the first control signal YC1. The first switch 1213 may not provide the first sub write current SWPGM1 with the write current WPGM when the first control signal YC1 is disabled, and may provide the first sub write current SWPGM1 with the write current WPGM when the first control signal YC1 is enabled. Therefore, the first switch 1213 selectively transmits the first sub write current SWPGM1 generated by the first driver 1211 to node d where the write current WPGM is applied, depending on the position of the memory cell which depends on the column address signal CA<0:n>. Therefore, the column sub driver 1210 may add the first sub write current SWPGM1 to the write current WPGM generated by the main driver 1100, thereby changing the magnitude of the write current WPGM.

The first driver 1211 may include a third PMOS transistor having a gate configured to receive the write control current WCC and a source connected to the power supply voltage. The first switch 1213 may include a fourth PMOS transistor having a gate configured to receive the first control signal YC1, a source connected to a drain of the third PMOS transistor, and a drain connected to node d.

The column sub driver 1210 may include a plurality of first drivers 1211 and first switches 1213, and the column position control section 1212 may generate a plurality of first control signals YC1. When the plurality of first control signals YC1, the plurality of first drivers 1211, and the plurality of first switches 1213 exist, the position of a memory cell may be subdivided to generate a write current which is most suitable for the position of the memory cell. Furthermore, it is possible to generate a write current suitable for a multi-level memory cell capable of storing two or more bits of data.

In FIG. 3, the row sub driver 1220 includes a second driver 1221, a row position control section 1222, and a second switch 1223. The second driver 1221 is configured to receive the write control current WCC to generate a second sub write current SWPGM2. The row position control section 1222 is configured to receive the row address signal RA<0:m> and generate a second control signal XC1. The row position control section 1222 senses the distance a memory cell is positioned from the write driver 100, in a similar manner to the column position control section 1212. Therefore, according to the row address signal RA<0:m>, the row position control section 1222 disables the second control signal XC1 when the memory cell is positioned closer to the write driver 100, and enables the second control signal XC1 when the memory cell is positioned farther from the write driver 100.

The second switch 1223 is configured to provide the second sub write current SWPGM2 to node d where the write current WPGM is applied, in response to the second control signal XC1. The second switch 1223 may not provide the second sub write current SWPGM2 with the write current WPGM when the second control signal XC1 is disabled, and may provide the second sub write current SWPGM2 with the write current WPGM when the second control signal XC1 is enabled. Therefore, the second switch 1223 selectively transmits the second sub write current SWPGM2 generated by the second driver 1221 to node d where the write current WPGM is applied, depending on the position of the memory cell according to the row address signal RA<0:m>. Therefore, the row sub driver 1220 may add the second sub write current SWPGM2 to the write current WPGM generated by the main driver 1100, thereby changing the magnitude of the write current WPGM2.

The second driver 1221 may include a fifth PMOS transistor having a gate configured to receive the write control current WCC and a source connected to the power supply voltage. The second switch 1223 may include a sixth PMOS transistor having a gate configured to receive the second control signal XC1, a source connected to a drain of the fifth PMOS transistor, and a drain connected to node d.

The row sub driver 1220 may further include a third driver 1224 and a third switch 1225, and the row position generation section 1222 may further generate a third control signal XC2. The third driver 1224 and the third switch 1225 are components which are added to perform substantially similar functions as the second driver 1221 and the second switch 1223, respectively, to generate an optimal write current WPGM by subdividing the position of the memory cell.

In an embodiment of the present invention, it has been described that the row position control section 1222 responds to the row address signal RA<0:m>. However, a decoding signal obtained by decoding the row address signal RA<0:m> may be used, and whether or not to enable the second and third control signals XC1 and XC2 may be based on the most significant bit (MSB) information of the decoding signal.

The sub write driver 1200 senses a row and column where a memory cell to store data is positioned, and provides an additional current to the write current WPGM generated by the main driver 1100 according to the sensed position, thereby changing the magnitude of the write current WPGM. The sub write driver 1200 may not provide an additional sub write current to a memory cell positioned closest to the write driver 100, but may additionally provide the largest sub write current to a memory cell positioned farthest from the write driver 100.

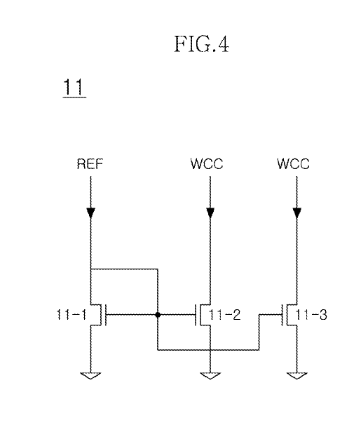

FIG. 4 is a diagram illustrating the configuration of the write control unit 11 of FIG. 2. Referring to FIG. 4, the write control unit 11 includes first to third NMOS transistors 11-1 to 11-3. The first NMOS transistor 11-1 has a gate and drain configured to receive a write reference current REF and a source connected to a ground voltage. The second NMOS transistor 11-2 has a gate configured to receive the write reference current REF, a source connected to the ground voltage, and a drain configured to generate the write control current WCC. The third NMOS transistor 11-3 has a gate configured to receive the write reference current REF, a source connected to the ground voltage, and a drain configured to generate the write control current WCC.

The write reference current REF is a current of which the magnitude is changed in response to a write command and data. That is, the write reference current REF is generated when a write operation is performed by the write command, and may have a magnitude which is changed depending on data to be stored in a memory cell. The first to third NMOS transistors 11-1 to 11-3 have a current mirror structure. Therefore, the write control current WCC generated by the second and third NMOS transistors 11-2 and 11-3 may have a substantially similar magnitude as the write reference current REF. The second and third NMOS transistors 11-2 and 11-3 may transmit the write control current WCC to different write drivers. For example, when the write control current WCC generated by the second NMOS transistor 11-2 is transmitted to the write driver 100 of FIG. 3, the write control current WCC generated by the third NMOS transistor 11-3 may be transmitted to a write driver allocated to another memory bank or another area of the same bank.

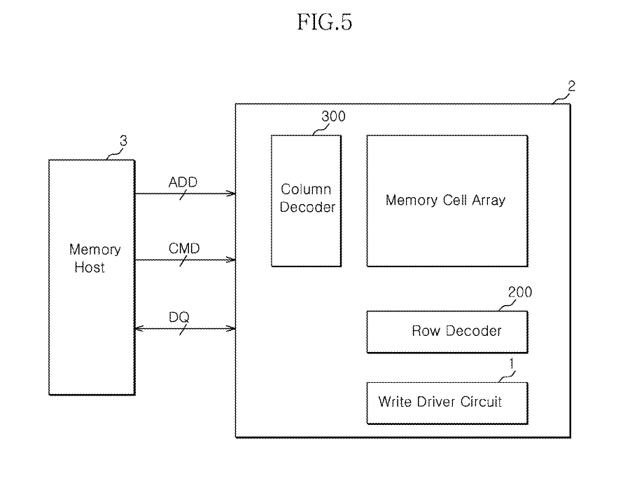

FIG. 5 is a block diagram schematically illustrating the configuration of a memory system according to another embodiment of the present invention. Referring to FIG. 5, the memory system includes a memory host 3 and a memory apparatus 2. The memory host 3 is configured to provide an address signal ADD including a row address and a column address to the memory apparatus 2. Furthermore, the memory host 3 provides a command signal CMD such as a read command or write command to the memory apparatus 3. The memory host 3 provides data DQ to be stored in the memory apparatus 2 during a write operation, and receives data DQ outputted from the memory apparatus 2 during a read operation. The memory host 3 may include a memory controller which is built in a single semiconductor apparatus such as a memory card or SSD with the memory apparatus 2. Furthermore, the memory host 3 may include a control device such as a central processing unit (CPU) or micro processor (MPU) which forms a computer system with the memory apparatus 2.

The memory apparatus 2 may receive the address signal ADD, the command signal CMD, and data DQ from the memory host 3 to perform a write operation or read operation. The memory apparatus 2 performs a write operation when receiving a write command from the memory controller 3. The memory apparatus 2 receives the address signal ADD from the memory controller 3 to select a specific memory cell of a memory cell array in which data is to be stored. The address signal ADD may be decoded by the row decoder 200 and the column decoder 300 so as to control the row switch 1400 and the column switch 1300 illustrated in FIG. 3. The write driver circuit 1 performs a write operation when receiving the write command, and generates a write current having a magnitude which changes in proportion to a distance to the specific memory cell to store the data DQ, thereby stably storing the data DQ in the specific memory cell.

While certain embodiments have been described above, it will be understood to those skilled in the art that the embodiments described are by way of example only. Accordingly, the semiconductor apparatus described herein should not be limited based on the described embodiments.

What is claimed is:

1. A write driver circuit comprising:
a write control unit configured to generate a write control current according to data to be stored; and
a write driver configured to generate a write current for writing the data into a memory cell, in response to the write control current and an address signal,
wherein the write driver changes the magnitude of the write current according to the write control current and the address signal.

2. The write driver circuit according to claim 1, wherein the address signal comprises a row address signal and a column address signal, and
the write driver increases the write current proportionally as a distance between the write driver and the memory cell to store the data increases, in response to the row address signal and the column address signal.

3. A write driver circuit comprising:
a write control unit configured to generate a write control current according to data to be stored;
a main write driver configured to generate a write current for writing the data into a memory cell, in response to the write control current; and
a sub write driver configured to generate the write current in response to the write control current and an address signal.

4. The write driver circuit according to claim 3, wherein the main write driver changes the magnitude of the write current in response to the write control current.

5. The write driver circuit according to claim 3, wherein the sub write driver changes the magnitude of the write current in response to the write control current and the address signal.

6. The write driver circuit according to claim 3, wherein the address signal comprises a row address signal and a column address signal, and
the sub write driver comprises:
a column sub driver configured to change the magnitude of the write current in response to the column address signal; and
a row sub driver configured to change the magnitude of the write current in response to the row address signal.

7. The write driver circuit according to claim 6, wherein the column sub driver comprises:
a first driver configured to generate a first sub write current in response to the write control current;
a column position control section configured to detect the column address signal and generate a first control signal; and
a first switch configured to provide the first sub write current to a node where the write current is applied, in response to the first control signal.

8. The write driver circuit according to claim 7, wherein the column position control section generates the first control signal in response to the column address signal.

9. The write driver circuit according to claim 7, wherein the row sub driver comprises:
a second driver configured to generate a second sub write current in response to the write control current;
a row position control section configured to detect the row address signal and generate a second control signal; and
a second switch configured to provide the second sub write current to the node where the write current is applied, in response to the second control signal.

10. The write driver circuit according to claim 9, wherein the row position control section receives the row address signal, detects the most significant bit (MSB) of the row address signal, and generates the second control signal.

11. A semiconductor apparatus comprising:
a write control unit configured to generate a write control current according to data to be stored;
a write driver configured to generate a write current having a magnitude which changes in proportion to a distance between the write driver and a memory cell to store the data, in response to the write control current;
a row switch connected to a word line to select the memory cell to store the data, in response to a row address signal; and
a column switch configured to select a bit line connected to the memory cell to store the data, in response to a column address signal.

12. The semiconductor apparatus according to claim 11, wherein the write driver comprises:
a main write driver configured to generate the write current in response to the write control current; and
a sub write driver configured to generate the write current in response to the write control current, the row address signal, and the column address signal.

13. The semiconductor apparatus according to claim 12, wherein the sub write driver comprises:
a column sub driver configured to change the magnitude of the write current in response to the column address signal; and
a row sub driver configured to change the magnitude of the write current in response to the row address signal.

14. The semiconductor apparatus according to claim 13, wherein the column sub driver comprises:
a first driver configured to generate a first sub write current in response to the write control current;
a column position control section configured to detect the column address signal and generate a first control signal; and
a first switch configured to provide the first sub write current to a node where the write current is applied, in response to the first control signal.

15. The semiconductor apparatus according to claim 14, wherein the row sub driver comprises:
a second driver configured to generate a second sub write current in response to the write control current;
a row position control section configured to detect the row address signal and generate a second control signal; and
a second switch configured to provide the second sub write current to the node where the write current is applied, in response to the second control signal.

16. The semiconductor apparatus according to claim 11, wherein the column switch comprises:
a bit line switch configured to select a bit line connected to the memory cell according to the column address signal; and
a global bit line switch configured to select a global bit line connected to the bit line according to the column address signal.

17. The semiconductor apparatus according to claim 11, wherein the memory cell comprises a resistive material, wherein
the resistive material has a resistance value that changes according to the write control current so as to store the data.

18. The semiconductor apparatus according to claim 11, wherein the memory cell comprises a phase change material, wherein
the phase change material has a crystalline structure that changes according to the write control current so as to store the data.

19. The semiconductor apparatus according to claim 11, wherein the memory cell comprises a magnetic material, wherein
the magnetic material has a magnetization direction that changes according to the write current so as to store the data.

20. A memory system comprising:
a memory host;
a write control unit configured to receive a command signal and data from the memory host and generate a write control current;
a write driver configured to generate a write current having a magnitude which is changed in proportion to a distance between the writer driver and a memory cell to store the data, in response to the write control current;
a row switch connected to a word line to select the memory cell to store the data, in response to a row address signal; and
a column switch configured to select a bit line connected to the memory cell to store the data, in response to a column address signal.
